(19) United States
(12) Patent Application Publication
(10) Pub. No.: US 2025/0234691 A1
(43) Pub. Date: Jul. 17, 2025

(54) DISPLAY APPARATUS AND ELECTRONIC DEVICE

(71) Applicant: Samsung Display Co., Ltd., Yongin-Si (KR)

(72) Inventors: Jinyool Kim, Yongin-si (KR); Inho Park, Yongin-si (KR)

(21) Appl. No.: 18/912,585

(22) Filed: Oct. 11, 2024

(30) Foreign Application Priority Data
Jan. 16, 2024 (KR) 10-2024-0006756

(51) Int. Cl. H01L 33/62; H01L 25/16; H01L 27/12

(52) U.S. Cl. CPC H10H 20/857; H01L 25/167; H10D 86/441; H10D 86/60

(57) ABSTRACT

Provided is a display apparatus including a substrate, a repair line disposed on the substrate, an insulating layer covering the repair line, a first thin-film transistor disposed in the insulating layer, a first connection line disposed on the insulating layer and at least a portion of the repair line, and a light-emitting element disposed on the first connection line and connected to the first connection line, wherein the insulating layer includes a first groove on the repair line.

### CROSS-REFERENCE TO RELATED APPLICATION

This application is based on and claims priority, under 35 U.S.C. § 119, to Korean Patent Application No. 10-2024-0006756 filed on Jan. 16, 2024 in the Korean Intellectual Property Office, the disclosure of which is incorporated by reference herein in its entirety.

### BACKGROUND

### 1. Field

One or more embodiments relate to a display apparatus, and more particularly, to a display apparatus including an organic light-emitting diode.

### 2. Description of the Related Art

Display apparatuses visually display data. A display apparatus may include a substrate divided into a display area and a peripheral area. A plurality of light-emitting elements may be provided in the display area. Each of the light-emitting elements may be connected to a corresponding thin-film transistor, and further to a sub-pixel circuit to receive a current.

In a display apparatus, some light emitting elements may malfunction due to errors during a manufacturing process. Such a malfunctioning light-emitting element may be repaired to operate properly. The repair process may entail disconnecting the malfunctioning light-emitting element from a corresponding sub-pixel circuit and connecting the light-emitting element to a dummy sub-pixel circuit provided in the peripheral area. In this case, a repair line may be provided, wherein the repair line overlaps a portion of a wiring of a light-emitting element and a portion of a wiring of a dummy sub-pixel circuit. The repair line may extend across a boundary between the display area and the peripheral area.

### SUMMARY

According to one or more embodiments, a display apparatus includes a substrate, a repair line disposed on the substrate, an insulating layer covering the repair line, a first thin-film transistor disposed in the insulating layer, a first connection line disposed on the insulating layer and at least a portion of the repair line, and a light-emitting element disposed on the first connection line and connected to the first connection line, wherein the insulating layer includes a first groove on the repair line.

A portion of the first connection line that is on the repair line may be disposed in the first groove.

The first thin-film transistor may include an active layer including a semiconductor, and the repair line may be disposed on a layer located under the active layer.

The first connection line may be disposed on a same layer as a source electrode or a drain electrode of the first thin-film transistor.

A first distance between an upper surface of the repair line and an upper surface of the insulating layer in a region overlapping the first groove may be about 20% to about 80% of a second distance between the upper surface of the repair line and the upper surface of the insulating layer in a region outside of the first groove.

A depth of the first groove may be about 20% to about 80% of a thickness of the insulating layer.

An edge of the repair line and an edge of the first groove are separated from each other in one of a first direction and a second direction by 1 μm or more.

The display apparatus may further include a neighboring line that is disposed under the insulating layer and is adjacent to the repair line, wherein a distance between the repair line and the neighboring line in one of a first direction and a second direction may be 2 μm or more.

In a plan view, the repair line may extend in a first direction, and the first connection line may extend in a second direction crossing the first direction.

A portion of the repair line may extend in the second direction and overlap the first connection line.

The insulating layer may include a first opening extending through the insulating layer between the repair line and a portion of the first connection line that is in the first groove.

The repair line and the first connection line may fill the first opening in the insulating layer and be in direct contact with each other.

The first connection line may be disconnected from the first thin-film transistor.

The display apparatus may further include a second thin-film transistor that is apart from the light-emitting element and the first thin-film transistor and is disposed in the insulating layer, and a second connection line connected to the second thin-film transistor, wherein the insulating layer may further include a second groove, and wherein the repair line, the second groove, and the second connection line may overlap.

The insulating layer may include a second opening extending through the insulating layer between the repair line and a portion of the second connection line that is in the second groove, wherein the repair line and the second connection line may fill the second opening of the insulating layer and be in direct contact with each other.

The display apparatus may include a display area in which the light-emitting element, the first thin-film transistor, and the first connection line are arranged, and a peripheral area in which the second thin-film transistor and the second connection line are arranged, wherein the peripheral area may at least partially surround the display area.

According to one or more embodiments, a display apparatus includes a substrate including a display area in which a light-emitting element is arranged, and a peripheral area surrounding the display area, a first thin-film transistor disposed on the substrate in the display area, a first connection line disposed on the first thin-film transistor in the display area, a second thin-film transistor disposed on the substrate in the peripheral area, a second connection line disposed on the second thin-film transistor in the peripheral area, a repair line extending continuously across the display area and the peripheral area, and an insulating layer disposed between the repair line and the first and second connection lines, wherein the repair line is disposed on a layer located under the first thin-film transistor and the second thin-film transistor.

The repair line may overlap a portion of the first connection line and a portion of the second connection line.

The insulating layer may include a first groove and a second groove, wherein the first groove overlaps the repair line and the first connection line, and the second groove overlaps the repair line and the second connection line.

At least one of a depth of the first groove and a depth of the second groove may be about 20% to about 80% of a thickness of the insulating layer.

The first connection line may be disposed on a same layer as a source electrode or a drain electrode of the first thin-film transistor.

The repair line may extend in a first direction, and at least one of the first connection line and the the second connection line may extend in a second direction crossing the first direction.

A portion of the repair line may extend in the second direction and overlap at least one of the first connection line and the second connection line.

The insulating layer may include a first opening extending through the insulating layer, wherein the first opening extends between the repair line and the first connection line, and a second opening extends between the repair line and the second connection line, and the repair line and the first connection line may fill the first opening and be in direct contact with each other, and the repair line and the second connection line may fill the second opening and be in direct contact with each other.

The light-emitting element may be electrically connected to the second thin-film transistor through the first connection line, the repair line, and the second connection line.

According to one or more embodiments, an electronic device includes a display apparatus, and a housing around the display apparatus, wherein the display apparatus includes a substrate, a repair line disposed on the substrate, an insulating layer on the repair line, a first thin-film transistor disposed in the insulating layer, a first connection line disposed on the insulating layer and overlapping at least a portion of the repair line, and a light-emitting element disposed on the first connection line and connected to the first connection line, wherein the insulating layer is thinner in a region above the repair line than in other regions.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic device according to an embodiment;

FIG. 2 is a schematic perspective view of a display apparatus according to an embodiment;

FIG. 3 is a schematic plan view of a display apparatus according to an embodiment;

FIG. 4 is a schematic enlarged plan view of a portion of a display apparatus according to an embodiment;

FIGS. 5A to 5C are enlarged plan views of a region in which a first connection line or a second connection line of FIG. 4 overlaps a repair line;

FIG. 6A is a cross-sectional view of a portion of a display apparatus according to an embodiment;

FIG. 6B is an enlarged cross-sectional view of a portion of the display apparatus of FIG. 6A;

FIG. 7A is a cross-sectional view of a portion of a display apparatus according to another embodiment;

FIG. 7B is an enlarged cross-sectional view of a portion of the display apparatus of FIG. 7A;

FIG. 8A is a cross-sectional view of a portion of a display apparatus according to another embodiment;

FIG. 8B is an enlarged cross-sectional view of a portion of the display apparatus of FIG. 8A;

FIGS. 9A to 9C are schematic plan views showing an operation in a process of manufacturing a display apparatus according to an embodiment; and

FIGS. 10A to 10C are cross-sectional views showing an operation of connecting a light-emitting diode to a second sub-pixel circuit in specific circumstances described with reference to FIGS. 3 and 4;

FIG. 11 is an enlarged cross-sectional view of a portion of FIG. 10C; and

FIGS. 12A to 12C are cross-sectional views showing an operation in a process of manufacturing a display apparatus according to an embodiment.

### DETAILED DESCRIPTION

Reference will now be made to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present. A first layer, region, or element being “under” a second layer, region, or element refers to an arrangement in which the second layer, region, or element is “on” the first layer, region, or element. Two layers, regions, or elements “overlapping” refers to one of the two layers, regions, or elements being on the other one of the two layers, regions, or elements without regard to which one is on top.

Sizes of elements in the drawings may be exaggerated or reduced for convenience of explanation. For example, the size and thickness of each element shown in the drawings are arbitrarily represented for convenience of description, and thus, the present disclosure is not necessarily limited to the relative dimensions depicted.

An X-axis, a Y-axis and a Z-axis are not limited to three axes of the rectangular coordinate system, and may be interpreted in a broader sense. For example, the X-axis, the Y-axis, and the Z-axis may be perpendicular to one another, or may represent different directions that are not perpendicular to one another.

In the case where a certain embodiment may be implemented differently, process steps may be performed in an order different from the described order. For example, two processes successively described may be simultaneously performed or performed in the reverse order.

A process of repairing a light-emitting element with a lighting defect may be as follows. First, a wiring of a light-emitting element connected to a corresponding sub-pixel circuit may be cut and disconnected. Then, a portion of a wiring of a light-emitting element and a portion of a repair line may be melted and cooled to connect to each other. Similarly, a portion of a wiring of a dummy sub-pixel circuit and a portion of the repair line may be melted and cooled to connect to each other. Accordingly, the light-emitting element may receive a current from the dummy sub-pixel circuit and operate normally.

In this case, in case of connecting a portion of a wiring of the light-emitting element to a portion of the repair line, or connecting a portion of a wiring of the dummy sub-pixel circuit to a portion of the repair line, when the thickness of an insulating layer between the wirings is thick, connection may fail.

Aspects will be set forth in part in the description which follows and, in part, will be apparent from the description, or may be learned by practice of the presented embodiments of the disclosure.

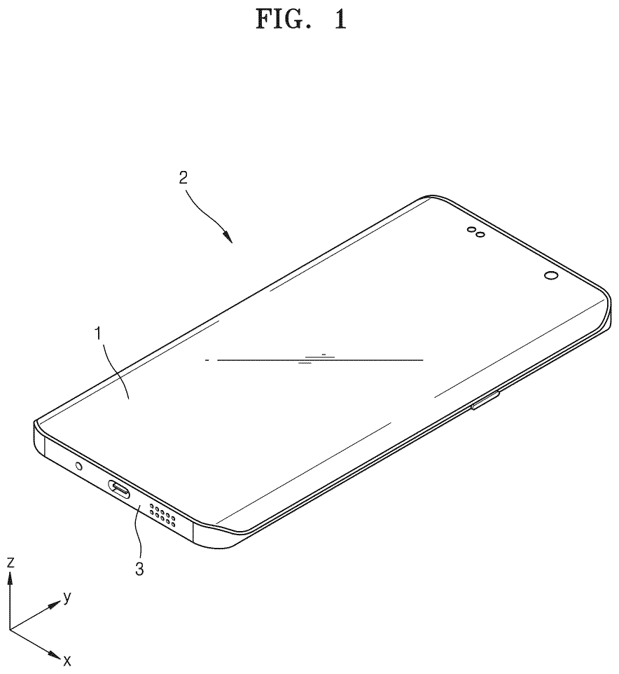

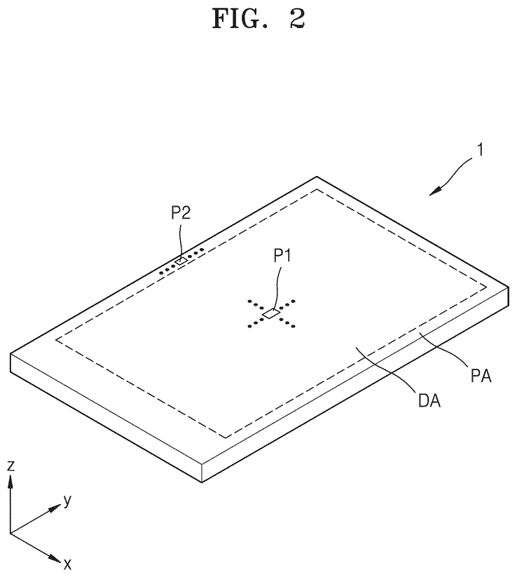

FIG. 1 is a schematic perspective view of an electronic device 2 according to an embodiment. FIG. 2 is a schematic perspective view of a display apparatus 1 according to an embodiment.

Referring to FIGS. 1 and 2, the display apparatus 1 is an apparatus configured to display moving or still images, and the electronic device 2 may be configured to display a screen or to input or output data. Although it is shown in FIG. 1 that the display apparatus 1 is used in a mobile phone, the disclosure is not limited thereto, and the display apparatus 1 may be used as a display screen of various electronic devices including televisions, notebook computers, monitors, advertisement boards, Internet of things (IoTs) as well as portable electronic devices including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus 1 according to an embodiment may be used in electronic devices such as wearable devices including smartwatches, watchphones, glasses-type displays, and head-mounted displays (HMDs). In addition, in an embodiment, the display apparatus 1 is applicable to a display screen in various electronic devices, such as a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

In an embodiment, the display apparatus 1 may be received in a housing 3 of the electronic device 2. The housing 3 may be a cover configured to protect inner elements such as the display apparatus 1 and form the appearance of the electronic device 2. In addition, the display apparatus 1 may be connected to an electronic module of the electronic device 2 and driven on the electronic device 2. Hereinafter, the display apparatus 1 is mainly described.

The display apparatus 1 may have an approximately rectangular shape as shown in FIG. 2. For example, the display apparatus 1 may have a generally rectangular planar shape with short sides extending in a first direction (e.g., an ±x direction) and long sides extending in a second direction (e.g., a ±y direction) as shown in FIG. 2. In an embodiment, a portion where a short side extending in the first direction meets a long side extending in the second direction may form an angle (e.g., a right angle) shape or a rounded shape having a preset curvature. In addition, the planar shape of the display apparatus 1 is not limited to rectangular shapes but may have other polygons, circular shapes, or elliptical shapes.

The display apparatus 1 may include a display area DA and a peripheral area PA. The display area DA may be configured to display images. First sub-pixels P1 may be arranged in the display area DA. Each first sub-pixel P1 may be configured to emit light by using a display element. In an embodiment, the first sub-pixels P1 may be configured to emit light of different colors from each other. In an embodiment, each first sub-pixel P1 may be configured to emit red, green, or blue light. In an embodiment, each first sub-pixel P1 may be configured to emit red, green, blue, or white light. The display apparatus 1 may be configured to display images by using light emitted from the first sub-pixels P1.

The peripheral area PA may be a non-display area in which images are not displayed. The peripheral area PA may surround at least a portion of the display area DA. For example, the peripheral area PA may surround the display area DA entirely. Second sub-pixels P2 may be arranged in the peripheral area PA. Each second sub-pixel P2 may include the same element as the first sub-pixel P1 and may be a dummy sub-pixel that does not include a display element and is configured not to emit light. For example, even when a display element included in the first sub-pixel P1 is connected to the second sub-pixel P2, the second sub-pixel P2 may be configured to equally emit light and display images. Hereinafter, although the second sub-pixel P2 is denoted by a ‘sub-pixel’, it should be understood that the second sub-pixel P2 does not include a display element and does not emit light. A driver, a power line, or the like may be arranged in the peripheral area PA, wherein the driver is configured to provide electrical signals to the first and second sub-pixels P1 and P2, and the power line is configured to provide power. For example, a scan driver may be arranged in the peripheral area PA, wherein the scan driver is configured to apply scan signals to the first and second sub-pixels P1 and P2. In addition, a data driver may be arranged in the peripheral area PA, wherein the data driver is configured to apply data signals to the first and second sub-pixels P1 and P2.

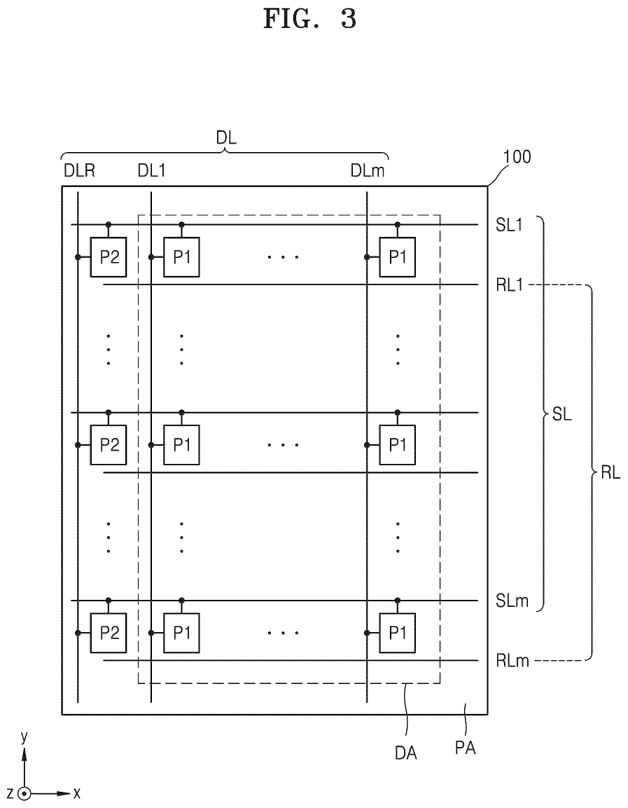

FIG. 3 is a schematic plan view of a display apparatus according to an embodiment.

Referring to FIG. 3, a plurality of scan lines SL, a plurality of data lines DL, a plurality of repair lines RL, the plurality of first sub-pixels P1, and the plurality of second sub-pixels P2 may be disposed on the substrate 100.

The first sub-pixel P1 may be arranged in the display area DA of the substrate 100, and the second sub-pixel P2 may be arranged in the peripheral area PA of the substrate 100. The plurality of scan lines SL, the plurality of data lines DL, and the plurality of repair lines RL may cross the display area DA and the peripheral area PA.

Each of the plurality of scan lines SL may extend in the first direction (e.g., the +x direction) and be apart from each other in the second direction (e.g., the +y direction). The extension direction and/or the separation direction of the plurality of scan lines SL are not limited thereto and may be variously changed. The plurality of scan lines SL may be respectively connected to thin-film transistors of corresponding first sub-pixel P1 and second sub-pixel P2. As an example, the thin-film transistors of the first sub-pixel P1 and second sub-pixel P2 aligned in the first direction (e.g., the +x direction) may be connected to the same scan line SL, for example, a first scan line SL1. A light-emitting element of the first sub-pixel P1 may be configured to emit light according to a signal of the scan line SL. Although it is shown in FIG. 3 that one scan line SL is connected to one first sub-pixel P1 or one second sub-pixel P2, the disclosure is not limited thereto. In another embodiment, the first sub-pixel P1 or second sub-pixel P2 may be simultaneously connected to the plurality of scan lines SL.

The plurality of data lines DL may extend in the second direction (e.g., the +y direction) and be apart from each other in the first direction (e.g., the +x direction). The extension direction and/or the separation direction of the plurality of data lines DL are not limited thereto and may be variously changed. Each of the plurality of data lines DL may be connected to a thin-film transistor of corresponding first sub-pixel P1 or second sub-pixel P2. For example, the thin-film transistors of the first sub-pixels P1 aligned in the second direction (e.g., the ty direction) may be connected to the same data line DL, for example, a first data line DL1. Alternatively, the thin-film transistors of the second sub-pixels P2 aligned in the second direction (e.g., the ty direction) may be connected to the same data line DL, for example, a repair data line DLR. A light-emitting element of the first sub-pixel P1 may be configured to emit light according to a signal of the data line DL. Although it is shown in FIG. 3 that one data line DL is connected to one first sub-pixel P1 or one second sub-pixel P2, the disclosure is not limited thereto. In another embodiment, the first sub-pixel P1 or second sub-pixel P2 may be simultaneously connected to the plurality of scan lines SL. The plurality of scan lines SL and the plurality of data lines DL may cross and be insulated from each other.

The plurality of repair lines RL may extend in the first direction (e.g., the +x direction) and be spaced apart from each other in the second direction (e.g., the ty direction). The extension direction and/or the separation direction of the plurality of repair lines RL are not limited thereto and may be variously changed. The plurality of repair lines RL and the plurality of data lines DL may cross and be insulated from each other. The repair line RL may be arranged to be adjacent to at least one first sub-pixel P1 and at least one second sub-pixel P2. As an example, the first scan line SL1 and the first repair line RLI may be arranged to face each other with the plurality of first sub-pixels P1 and the plurality of second sub-pixels P2 aligned in the first direction (e.g., the +x direction) therebetween. In a specific circumstance, the repair line RL may be connected to a specific first sub-pixel P1 and an arbitrary second sub-pixel P2, which are described below.

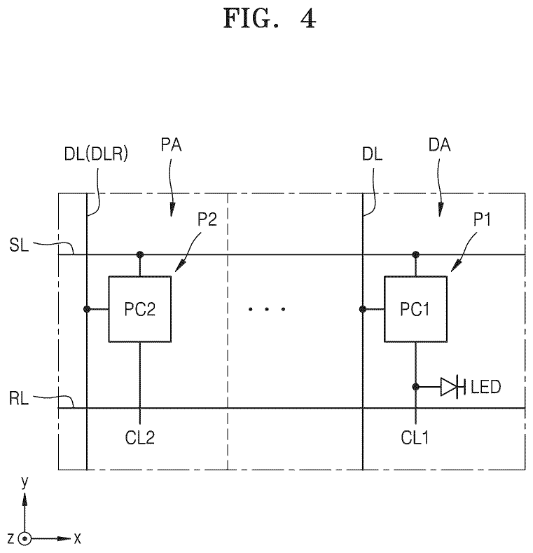

FIG. 4 is a schematic enlarged plan view of a portion of a display apparatus according to an embodiment.

Referring to FIG. 4, one first sub-pixel P1, one second sub-pixel P2, one scan line SL, one repair line RL, the data line DL connected to the first sub-pixel P1, and the data line DL connected to the second sub-pixel P2, or the repair line DRL are shown.

As described with reference to FIG. 3, the scan line SL and the repair line RL may extend in the first direction (e.g., the ±x direction), and the data line DL may extend in the second direction (e.g., the ±y direction). The first sub-pixel P1 may include a first sub-pixel circuit PC1 including thin-film transistors and wirings. The second sub-pixel P2 may include a second sub-pixel circuit PC2 including thin-film transistors and wirings. Each of the first sub-pixel circuit PC1 and the second sub-pixel circuit PC2 may be connected to the scan line SL and the data line DL.

The first sub-pixel P1 may include a first connection line CL1 connected to the first sub-pixel circuit PC1 and extending in the second direction (e.g., the ty direction). The first connection line CL1 may be connected to a light-emitting diode LED, which is a display element. The first connection line CL1 may overlap the repair line RL. As an example, the first connection line CL1 may cross and overlap the repair line RL in a plan view. Similarly, the second sub-pixel P2 may include a second connection line CL2 connected to the second sub-pixel circuit PC2 and extending in the second direction (e.g., the ty direction). Unlike the first connection line CL1, the second connection line CL2 may not be connected to a separate display element. The second connection line CL2 may overlap the repair line RL. For example, the second connection line CL2 may cross and overlap the repair line RL in a plan view.

Under most conditions in which the first sub-pixel circuit PC1 and the light-emitting diode LED normally operate, the first connection line CL1 is insulated from the repair line RL, and the second connection line CL2 is insulated from the repair line RL. Accordingly, the light-emitting diode LED may be connected to the first sub-pixel circuit PC1 and may not be connected to the second sub-pixel circuit PC2. Sometimes, for example, if the first sub-pixel circuit PC1 does not operate as expected due to a defect, the light emitting diode LED may not operate as expected. In an embodiment of the disclosure, the first connection line CL1 and the second connection line CL2 may be connected to the repair line RL. In this case, the light emitting diode LED may be connected to the second sub-pixel circuit PC2 and be turned on to operate as expected. A method of connecting the first connection line CL1 and the second connection line CL2 to the repair line RL in the specific circumstance is described below in detail.

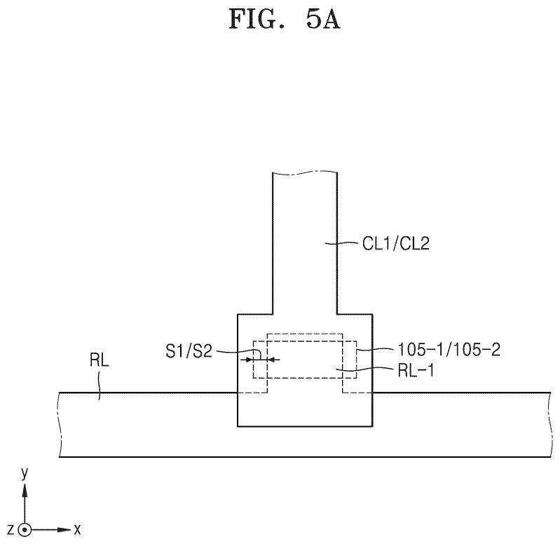

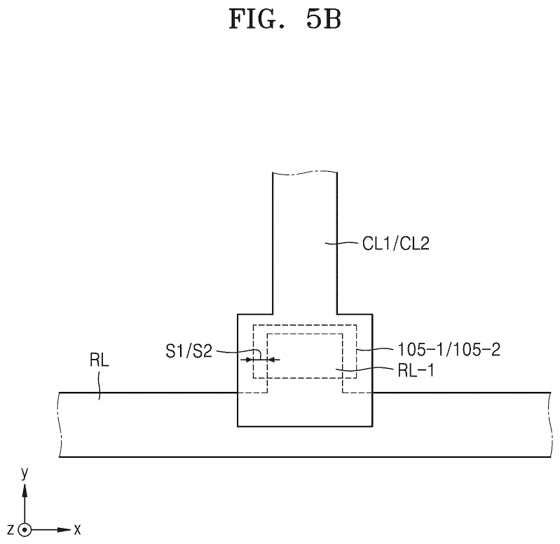

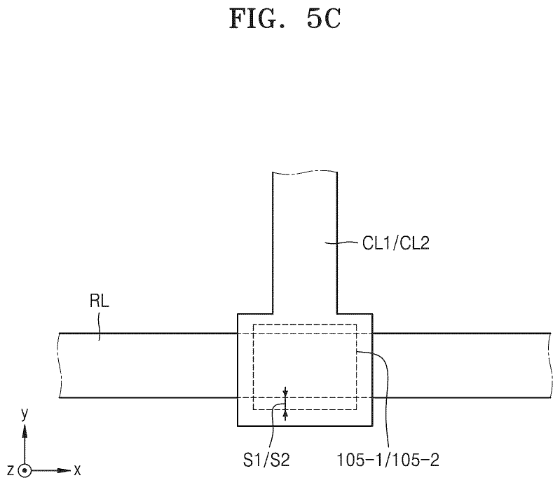

FIGS. 5A to 5C are enlarged plan views of a region in which the first connection line CL1 or the second connection line CL2 of FIG. 4 overlaps the repair line RL.

Referring to FIGS. 5A, 5B, and 5C, the first connection line CL1 or the second connection line CL2 may extend in the second direction (e.g., the ty direction), and the repair line RL may extend in the first direction (e.g., the ±x direction). Hereinafter, for convenience, the description will focus on a relationship between the first connection line CL1 and the repair line RL; however, it should be understood that the same content is also applicable to a relationship between the second connection line CL2 and the repair line RL.

An end of the first connection line CL1 may overlap only a portion of the repair line RL as shown in FIGS. 5A and 5B, or the end of the first connection line CL1 may entirely overlap the repair line RL to cross the repair line RL in the second direction (e.g., the ty direction) as shown in FIG. 5C. Although it is shown in FIGS. 5A to 5C that the end of the first connection line CL1 that overlaps the repair line RL has a greater width or length in the first direction (e.g., the ±x direction) than the other portion of the first connection wire CL1, the disclosure is not limited thereto. In another embodiment, the first connection line CL1 may have, along the second direction (e.g., the ±y direction), a constant length in the first direction (e.g., the ±x direction).

Referring to FIGS. 5A and 5B in more detail, a portion of the repair line RL may extend in the second direction (e.g., the ±y direction) toward the first connection line CL1. As an example, the repair line RL may include a protrusion RL-1 protruding toward the ±y direction and overlapping the first connection line CL1. The protrusion RL-1 may entirely overlap the first connection line CL1. Although it is shown in FIGS. 5A and 5B that the shape of the protrusion RL-1 is approximately quadrangular, the disclosure is not limited thereto and the shape of the protrusion RL-1 may be variously modified to a triangle, a semicircle, and the like.

An insulating layer described below may be disposed between the repair line RL and the first connection line CL1. A first groove 105-1 may be disposed in the insulating layer disposed between the protrusion RL-1 of the repair line RL and the first connection line CL1. A second groove 105-2 may be disposed in the insulating layer disposed between another protrusion RL-1 of the repair line RL and the second connection line CL2. The first groove 105-1 and the second groove 105-2 may extend beyond a partial edge of the protrusion RL-1. As an example, the first groove 105-1 may extend by a first interval S1 beyond the edge of the protrusion RL-1, and the second groove 105-2 may extend by a second interval S2 beyond the edge of the protrusion RL-1. As shown in FIG. 5A, the first groove 105-1 and the second groove 105-2 may extend in the ±x direction beyond the edge of the protrusion RL-1. Alternatively, as shown in FIG. 5B, the first groove 105-1 and the second groove 105-2 may extend in the ±x direction and ty direction beyond the edge of the protrusion RL-1. Alternatively, as shown in FIG. 5C, the first groove 105-1 and the second groove 105-2 may extend in the ty direction beyond the edge of the repair line RL.

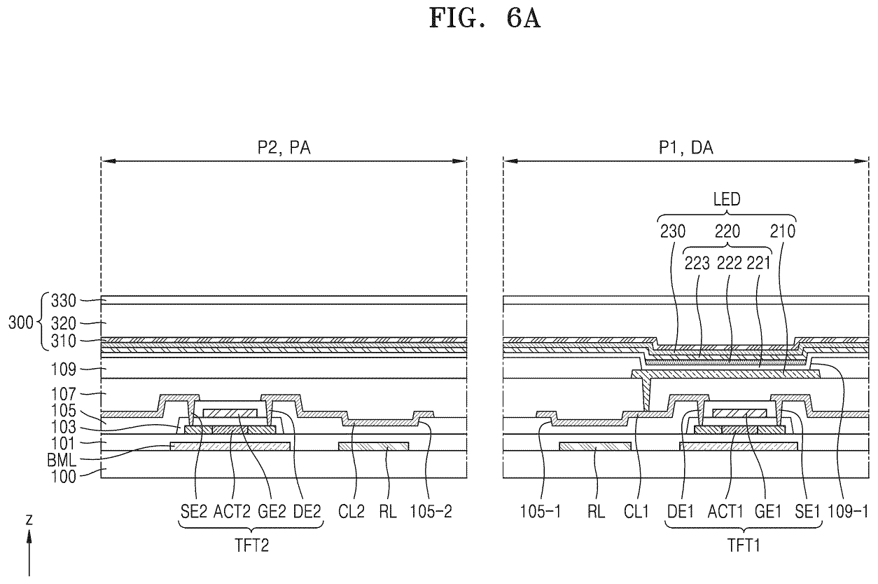

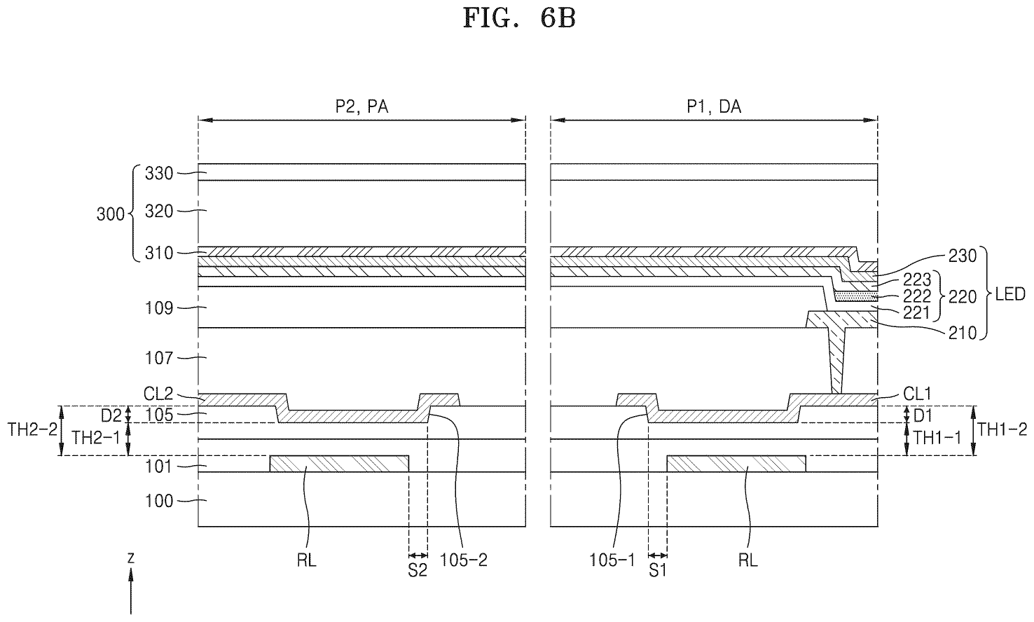

FIG. 6A is a cross-sectional view of a portion of a display apparatus according to an embodiment. FIG. 6B is an enlarged cross-sectional view of a portion of the display apparatus of FIG. 6A.

Referring to FIG. 6A, the first sub-pixel P1 and the second sub-pixel P2 are disposed on the substrate 100. The first sub-pixel P1 may be arranged in the display area DA. The first sub-pixel P1 may include a first thin-film transistor TFT1 and the light-emitting diode LED disposed on the substrate 100. The second sub-pixel P2 may be arranged in the peripheral area PA. The second sub-pixel P2 may include a second thin-film transistor TFT2 disposed on the substrate 100.

The substrate 100 may include glass or polymer resin. Polymer resin includes polyethersulfone (PESU), polyacrylate, polyether imide (PEI), polyethylene naphthalate (PEN), polyethylene terephthalate (PET), polyphenylene sulfide (PPS), polyarylate (PAR), polyimide (P1), or polycarbonate (PC). The substrate 100 including the polymer resin may be flexible, rollable, or bendable. The substrate 100 may have a multi-layered structure including a layer that includes the polymer resin and an inorganic layer.

A bottom metal layer BML may be disposed on the substrate 100 and may overlap first and second active layers ACT1 and ACT2 of the first and second thin-film transistors TFT1 and TFT2 described below. The bottom metal layer BML may be configured to block light reaching the first and second thin-film transistors TFT1 and TFT2, wherein the light is incident from below the substrate 100. The bottom metal layer BML may include a light-blocking material. In an embodiment, the bottom metal layer BML may include a light-blocking metal such as chromium (Cr) or molybdenum (Mo).

The repair line RL may be disposed on the same layer as the bottom metal layer BML. Accordingly, it may be understood that the repair line RL is disposed on a layer located that is between the substrate and the layers of the first and second active layers ACT1 and ACT2 of the first and second thin-film transistors TFT1 and TFT2 described below. In an embodiment, the repair line RL may include the same material as that of the bottom metal layer BML. In an embodiment, the repair line RL may be formed during the same process as a process of forming the bottom metal layer BML. In the description below, it is reasonable to understand that the repair line RL existing in each of the display area DA and the peripheral area PA is not a separate part but an integral part. For example, because a portion of the repair line RL arranged in the display area DA overlaps the first connection line CL1, the portion of the repair line RL may be the protrusion RL-1 (see FIG. 5A) of the repair line RL formed in the display area DA. Similarly, because a portion of the repair line RL arranged in the peripheral area PA overlaps the second connection line CL2, the portion of the repair line RL may be the protrusion RL-1 (see FIG. 5A) of the repair line RL formed in the peripheral area PA.

A buffer layer 101 may be disposed on the substrate 100 and may cover the bottom metal layer BML and the repair line RL. The buffer layer 101 may be configured to prevent the penetration of impurities and moisture. The buffer layer 101 may include an inorganic insulating material such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ).

The first and second thin-film transistors TFT1 and TFT2 may be disposed on the buffer layer 101. The first thin-film transistor TFT1 may include the first active layer ACT1, a first gate electrode GE1, a first source electrode SE1, and a first drain electrode DE1. The second thin-film transistor TFT2 may include the second active layer ACT2, a second gate electrode GE2, a second source electrode SE2, and a second drain electrode DE2.

The first active layer ACT1 and the second active layer ACT2 may be disposed on the buffer layer 101. Each of the first and second active layers ACT2 may overlap the corresponding bottom metal layer BML. In an embodiment, the area of the bottom metal layer BML may be greater than the areas of the first and second active layers ACT1 and ACT2. The first and second active layers ACT1 and ACT2 may include polycrystalline silicon, amorphous silicon, or a semiconductor including oxide, and include an organic semiconductor. The first and second active layers ACT1 and ACT2 may include a channel region, a drain region, and a source region, the drain region and the source region being on two opposite sides of the channel region.

A gate insulating layer 103 may be disposed to cover each of the first and second active layers ACT1 and ACT2. The gate insulating layer 103 may include an inorganic insulating material such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ). The gate insulating layer 103 may individually cover each of the first active layer ACT1 and the second active layer ACT2, and unlike FIG. 6A, the gate insulating layer 103 may be disposed to cover the buffer layer 101 entirely.

The first gate electrode GE1 may be disposed on the gate insulating layer 103 and may overlap the channel region of the first active layer ACT1. The second gate electrode GE2 may be disposed on the gate insulating layer 103 and may overlap the channel region of the second active layer ACT2. The first and second gate electrodes GE1 and GE2 may include at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), and include a single layer or a multi-layered structure including the above materials.

An interlayer insulating layer 105 may cover the first and second gate electrodes GE1 and GE2. In addition, the interlayer insulating layer 105 may be disposed to cover the gate insulating layer 103 and the buffer layer 101 entirely.

The interlayer insulating layer 105 may include contact holes respectively overlapping the source region and the drain region of the first active layer ACT1 and the source region and the drain region of the second active layer ACT2. Source electrodes and drain electrodes described below may be respectively connected to the active layer through the contact holes.

The interlayer insulating layer 105 may include the first groove 105-1 overlapping the repair line RL. A portion of the first groove 105-1, but less than all of the first groove 105-1, may overlap the repair line RL. Similarly, the interlayer insulating layer 105 may include the second groove 105-2 overlapping the repair line RL. A portion of the second groove 105-2, but less than all of the second groove 105-2, may overlap the repair line RL. The first groove 105-1 and the second groove 105-2 are formed by the interlayer insulating layer 105 being thinner than in the surrounding areas.

The first source electrode SE1, the first drain electrode DE1, the second source electrode SE2, the second drain electrode DE2, the first connection line CL1, and the second connection line CL2 may be disposed on the interlayer insulating layer 105. The first source electrode SE1 may overlap the source region of the first active layer ACT1 and be connected to the first active layer ACT1 through a contact hole formed in the interlayer insulating layer 105 and the gate insulating layer 103. In an embodiment, the first source electrode SE1 may be integrally formed with other neighboring lines. The second source electrode SE2 may overlap the source region of the second active layer ACT2 and be connected to the second active layer ACT2 through a contact hole formed in the interlayer insulating layer 105 and the gate insulating layer 103. In an embodiment, the second source electrode SE2 may be integrally formed with other neighboring lines.

The first drain electrode DE1 may overlap the drain region of the first active layer ACT1 and be connected to the first active layer ACT1 through a contact hole formed in the interlayer insulating layer 105 and the gate insulating layer 103. The first connection line CL1 may overlap the first groove 105-1 and be partially disposed in the first groove 105-1. Accordingly, a portion of the first connection line CL1 may overlap the repair line RL. In an embodiment, the first connection line CL1 and the first drain electrode DE1 may be connected to each other. In an embodiment, the first connection line CL1 and the first drain electrode DE1 may be integrally formed. In other words, a portion of the same line may be the first connection line CL1, and another portion of the same line may be the first drain electrode DE1.

The second drain electrode DE2 may overlap the drain region of the second active layer ACT2 and be connected to the second active layer ACT2 through a contact hole formed in the interlayer insulating layer 105 and the gate insulating layer 103. The second connection line CL2 may overlap the second groove 105-2 and be partially disposed in the second groove 105-2. Accordingly, a portion of the second connection line CL2 may overlap the repair line RL. In an embodiment, the second connection line CL2 and the second drain electrode DE2 may be connected to each other. In an embodiment, the second connection line CL2 and the second drain electrode DE2 may be integrally formed. In other words, a portion of the same line may be the second connection line CL2, and another portion of the same line may be the second drain electrode DE2.

The source electrode and drain electrode have the same physical properties and may be interchanged depending on specific conditions, such as the direction of current. In other words, in another embodiment, the first connection line CL1 may be integrally formed with the first source electrode SE1, and the second connection line CL2 may be integrally formed with the second source electrode SE2.

A via layer 107 may be disposed on the interlayer insulating layer 105 to entirely cover the first and second source electrodes SE1 and SE2, the first and second drain electrodes DE1 and DE2, and the first and second connection lines CL1 and CL2. The via layer 107 may include an organic insulating material such as acrylic, benzocyclobutene (BCB), polyimide (P1), or hexamethyldisiloxane (HMDSO). The via layer 107 may include a via hole overlapping the first connection line CL1. Although FIG. 6A shows a single via layer 107, the disclosure is not limited thereto. In another embodiment, the via layer may be provided in plurality, and a connection metal may be disposed between the respective via layers to electrically connect a sub-pixel electrode 210 to the first connection line CL1.

The sub-pixel electrode 210 may be disposed on the via layer 107 in the display area DA. The sub-pixel electrode 210 may be connected to the first connection line CL1 through a via hole formed in the via layer 107. The sub-pixel electrode 210 may be formed to be a (semi) transparent electrode or a reflective electrode. In the case where the sub-pixel electrode 210 is formed to be a (semi) transparent electrode, the sub-pixel electrode 210 may include indium tin oxide (ITO), indium zinc oxide (IZO), zinc oxide (ZO), indium oxide (IO), indium gallium oxide (IGO), or aluminum zinc oxide (AZO). In the case where the sub-pixel electrode 210 is formed to be a reflective electrode, the sub-pixel electrode 210 may include a reflective layer and a layer including ITO, IZO, ZnO, or In2O3, wherein the reflective layer includes silver (Ag), magnesium (Mg), aluminum (Al), platinum (Pt), palladium (Pd), gold (Au), nickel (Ni), neodymium (Nd), iridium (Ir), chromium (Cr) or compound thereof. In an embodiment, the sub-pixel electrode 210 may have a structure of an ITO layer, an Ag layer, and an ITO layer that are sequentially stacked. However, the disclosure is not limited thereto and the sub-pixel electrode 210 may include various materials, and the structure thereof may be a single layer or a multi-layer and be variously modified.

A bank layer 109 may be disposed on the via layer 107 to cover edge regions (or the edges) of the sub-pixel electrode 210. In other words, the bank layer 109 may include an opening exposing the central portion of the sub-pixel electrode 210. An opening 109-1 of the bank layer 109 may define an emission area of the light-emitting diode LED. Accordingly, the size and shape of the emission area of the light-emitting diode LED may be determined by the opening 109-1 of the bank layer 109.

An intermediate layer 220 may be disposed on the sub-pixel electrode 210. The intermediate layer 220 may include a first common layer 221 and a second common layer 223 disposed on the bank layer 111, and an emission layer 222 disposed in the opening of the bank layer 111. In an embodiment, the first common layer 221 may be disposed on the bank layer 111, the emission layer 222 may be disposed in the opening of the bank layer 111 on the first common layer 221, and the second common layer 223 may be disposed on the first common layer 221 to cover the emission layer 222. In other words, the emission layer 222 may be disposed in the opening of the bank layer 111 and disposed between the first and second common layers 221 and 223.

The emission layer 222 may include an organic emission layer including a low-molecular weight material or a polymer material. The first common layer 221 may include an electron transport layer (ETL) and/or an electron injection layer (EIL). The second common layer 223 may include a hole transport layer (HTL) and/or a hole injection layer (HIL). In an embodiment, the first common layer 221 or the second common layer 223 may be omitted. In an embodiment, the positions of the first common layer 221 and the second common layer 223 may be interchangeable.

An opposite electrode 230 may be disposed on the intermediate layer 220. As an example, the opposite electrode 230 may be disposed on the second common layer 223. The opposite electrode 230 may be disposed to entirely cover the intermediate layer 220. The opposite electrode 230 may include a conductive material having a low work function. As an example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 230 may further include a layer on the (semi) transparent layer, the layer including ITO, IZO, ZnO, or In2O3.

An encapsulation layer 300 may be disposed on the opposite electrode 230. The encapsulation layer 300 may include at least one inorganic layer and at least one organic layer. In an embodiment, the encapsulation layer 300 may include a first inorganic encapsulation layer 310, a second inorganic encapsulation layer 330, and an organic encapsulation layer 320 therebetween. The first and second inorganic encapsulation layers 310 and 330 may include at least one inorganic insulating material among silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO). The organic encapsulation layer 320 may include a polymer-based material. The polymer-based material may include a silicon-base resin, an acryl-based resin, an epoxy-based resin, polyimide, and polyethylene.

Hereinafter, a relationship between the repair line RL, the first connection line CL1, the second connection line CL2, the interlayer insulating layer 105, and the buffer layer 101 is described in detail with reference to FIG. 6B.

As described above, the interlayer insulating layer 105 may include the first groove 105-1 overlapping the repair line RL. The width of the first groove 105-1 may be equal to or greater than the width of the repair line RL. A portion of the first connection line CL1 may be disposed in the first groove 105-1. Accordingly, the first connection line CL1, the first groove 105-1, and the repair line RL may at least partially overlap each other. As described with reference to FIGS. 5A to 5C, a portion of the first groove 105-1 may extend beyond the edge of the repair line RL. Accordingly, it may be understood that a portion of the first connection line CL1 arranged inside the first groove 105-1 extends beyond the edge of the repair line RL. A length by which the first groove 105-1 extends beyond the edge of the repair line RL may be defined as a first interval S1. In an embodiment, the first interval S1 may be about 1 μm or more.

The depth of the first groove 105-1 may be defined as a first depth D1. In a region that overlaps the first groove 105-1, a distance between the upper surface of the repair line RL and the upper surface of the interlayer insulating layer 105 may be defined as a first-1 thickness TH1-1. In addition, in a region that does not overlap the first groove 105-1, a distance between the upper surface of the repair line RL and the upper surface of the interlayer insulating layer 105 may be defined as a first-2 thickness TH1-2. Accordingly, the first-2 thickness TH1-2 may be understood as a sum of the first-1 thickness TH1-1 and the first depth D1. In an embodiment, the first-1 thickness TH1-1 may be about 20% to about 80% of the first-2 thickness TH1-2. In an embodiment, the first depth D1 may be about 20% to about 80% of the first-2 thickness TH1-2.

In addition, the interlayer insulating layer 105 may include the second groove 105-2 overlapping the repair line RL. The width of the second groove 105-2 may be equal to or greater than the width of the repair line RL. A portion of the second connection line CL2 may be disposed in the second groove 105-2. Accordingly, the second connection line CL2, the second groove 105-2, and the repair line RL may at least partially overlap each other. As described with reference to FIGS. 5A to 5C, a portion of the second groove 105-2 may extend beyond the edge of the repair line RL. Accordingly, it may be understood that a portion of the second connection line CL2 arranged inside the second groove 105-2 extends beyond the edge of the repair line RL. A length by which the second groove 105-2 extends beyond the edge of the repair line RL may be defined as a second interval S2. In an embodiment, the second interval S2 may be about 1 μm or more.

The depth of the second groove 105-2 may be defined as a second depth D2. In a region that overlaps the second groove 105-2, a distance between the upper surface of the repair line RL and the upper surface of the interlayer insulating layer 105 may be defined as a second-1 thickness TH2-1. In addition, in a region that does not overlap the second groove 105-2, a distance between the upper surface of the repair line RL and the upper surface of the interlayer insulating layer 105 may be defined as a second-2 thickness TH2-2. Accordingly, the second-2 thickness TH2-2 may be understood as a sum of the second-1 thickness TH2-1 and the second depth D2. In an embodiment, the second-1 thickness TH2-1 may be about 20% to about 80% of the second-2 thickness TH2-2. In an embodiment, the second depth D2 may be about 20% to about 80% of the second-2 thickness TH2-2.

In an embodiment, the configuration of the first connection line CL1, the second connection line CL2, the first groove 105-1, and the second groove 105-2 may be symmetrical in the first sub-pixel P1 and the second sub-pixel P2. As an example, in an embodiment, the first depth D1 may be substantially equal to the second depth D2. In an embodiment, the first-1 thickness TH1-1 may be substantially equal to the second-1 thickness TH2-1. In an embodiment, the first-2 thickness TH1-2 may be substantially equal to the second-2 thickness TH2-2.

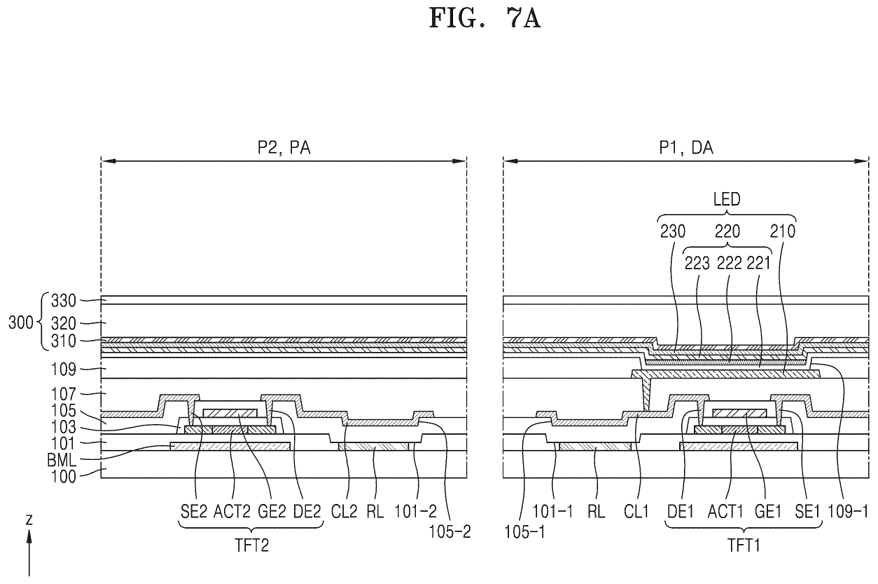

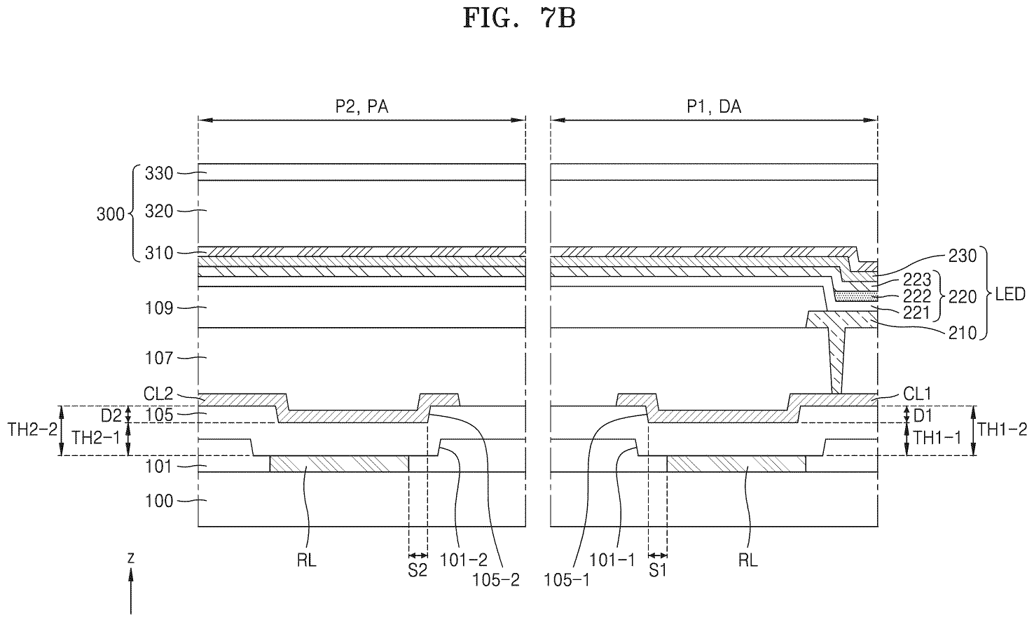

FIG. 7A is a cross-sectional view of a portion of a display apparatus according to another embodiment. FIG. 7B is an enlarged cross-sectional view of a portion of the display apparatus of FIG. 7A.

Referring to FIGS. 7A and 7B, the buffer layer 101 may include a first lower groove 101-1 and a second lower groove 101-2 that overlap the repair line RL. A portion of the interlayer insulating layer 105 may be disposed inside the first lower groove 101-1 and the second lower groove 101-2. In an embodiment, the interlayer insulating layer 105 may not be a planarization layer and it may be understood that the first groove 105-1 and the second groove 105-2 are generated by the first lower groove 101-1 and the second lower groove 101-2 during a process of disposing the interlayer insulating layer 105 on the buffer layer 101.

In an embodiment, the depth of the first lower groove 101-1 may be equal to the first depth D1. In an embodiment, the depth of the second lower groove 101-2 may be equal to the second depth D2. In an embodiment, the depth of the first lower groove 101-1 and the depth of the second lower groove 101-2 may be equal to each other.

Although it is shown in FIGS. 7A and 7B that the interlayer insulating layer 105 is in direct contact with the repair line RL by the first lower groove 101-1 and the second lower groove 101-2, the disclosure is not limited thereto. In another embodiment, the first lower groove 101-1 and/or the second lower groove 101-2 may be formed such that a portion of the buffer layer 101 remains on the upper surface of the repair line RL.

FIG. 7B depicts an embodiment that is similar to the embodiment of FIG. 6B except the surface of the interlayer insulating layer 105 that is closest to the substrate 100 is not planar. In a region that overlaps the first groove 105-1, a distance between the upper surface of the repair line RL and the upper surface of the interlayer insulating layer 105 may be defined as a first-1 thickness TH1-1. In a region that does not overlap the first groove 105-1, a distance between the upper surface of the repair line RL and the upper surface of the interlayer insulating layer 105 may be defined as a first-2 thickness TH1-2. Similarly, in a region that overlaps the second groove 105-2, a distance between the upper surface of the repair line RL and the upper surface of the interlayer insulating layer 105 may be defined as a second-1 thickness TH2-1. In a region that does not overlap the second groove 105-2, a distance between the upper surface of the repair line RL and the upper surface of the interlayer insulating layer 105 may be defined as a second-2 thickness TH2-2. In the embodiment of FIG. 7B, the depth of the groove 101-1 is part of the first-2 thickness TH1-2, and the depth of the groove 101-2 is part of the second-2 thickness TH2-2.

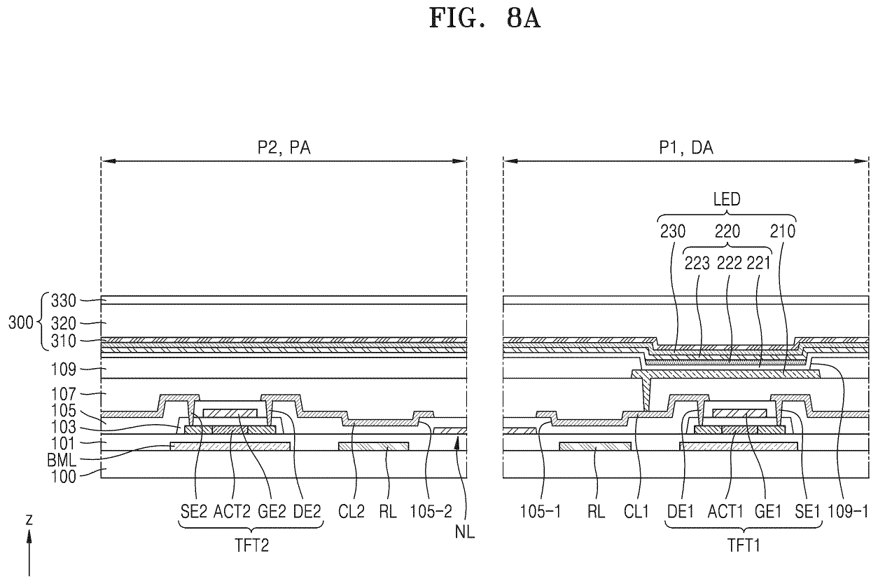

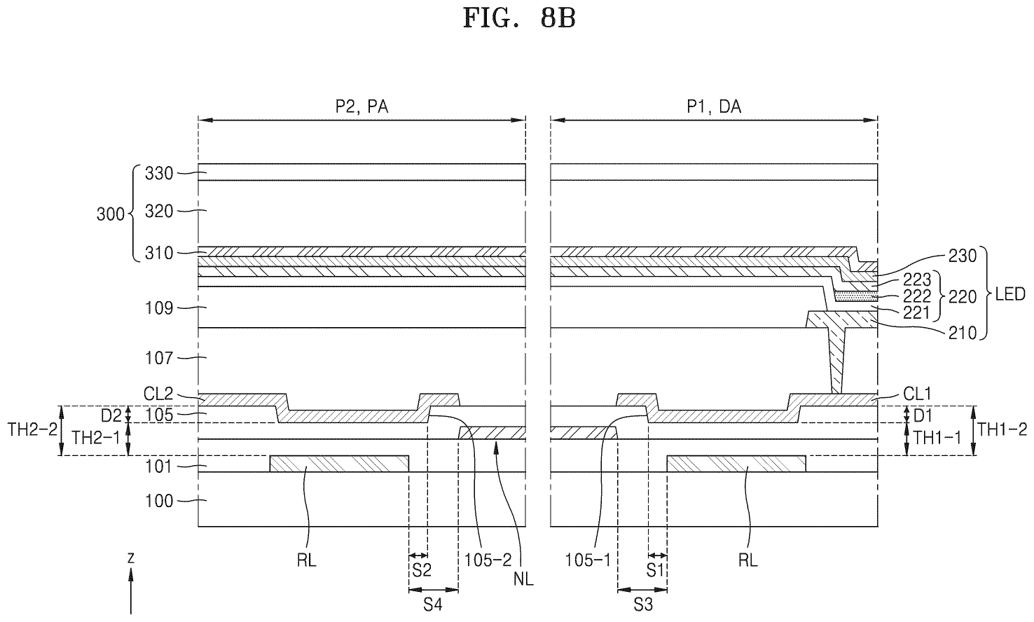

FIG. 8A is a cross-sectional view of a portion of a display apparatus according to another embodiment. FIG. 8B is an enlarged cross-sectional view of a portion of the display apparatus of FIG. 8A.

Referring to FIG. 8A, neighboring lines NL may be additionally disposed between the buffer layer 101 and the interlayer insulating layer 105. The neighboring lines NL may be arranged in only the display area DA, or arranged in only the peripheral area PA. As shown in FIG. 8A, the neighboring lines NL may be arranged in both the display area DA and the peripheral area PA. The neighboring lines NL may be disposed on the same layer as the first gate electrode GE1 and the second gate electrode GE2. In an embodiment, the neighboring lines NL may include the same materials as those of the first gate electrode GE1 and the second gate electrode GE2. In an embodiment, the neighboring lines NL may be formed during the same process as a process of forming the first gate electrode GE1 and the second gate electrode GE2. In an embodiment, the neighboring line NL, the first gate electrode GE1, and/or the second gate electrode GE2 may denote different portions of the same line.

Referring to FIG. 8B, the neighboring lines NL and the repair line RL may be distanced from each other. A distance between one edge of the repair line RL located in a region overlapping the first groove 105-1 and one edge of the neighboring line NL adjacent to the first groove 105-1 may be defined as a third interval S3. In an embodiment, the third interval S3 may be greater than the first interval S1. In an embodiment, the third interval S3 may be approximately twice or more than the first interval S1. In an embodiment, the third interval S3 may be about 2 μm or more.

A distance between one edge of the repair line RL located in a region overlapping the second groove 105-2 and one edge of the neighboring line NL adjacent to the second groove 105-2 may be defined as a fourth interval S4. In an embodiment, the fourth interval S4 may be greater than the second interval S2. In an embodiment, the fourth interval S4 may be approximately twice or more than the second interval S2. In an embodiment, the fourth interval S4 may be about 2 μm or more.

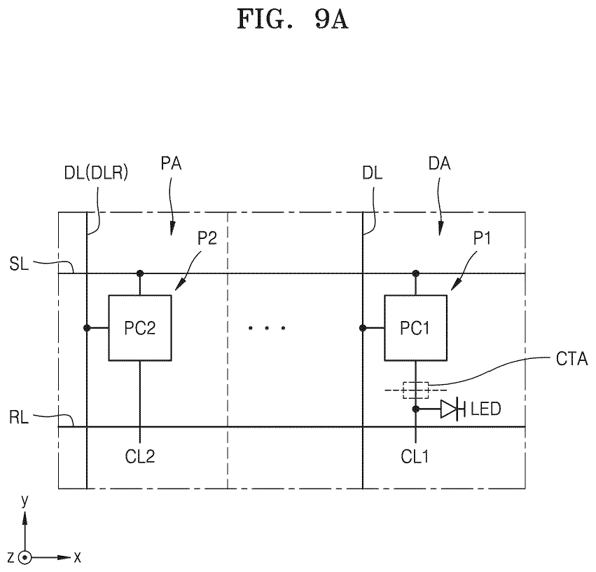

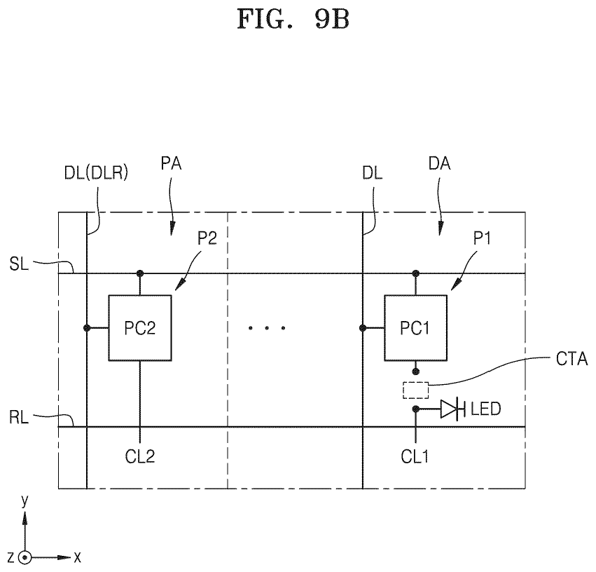

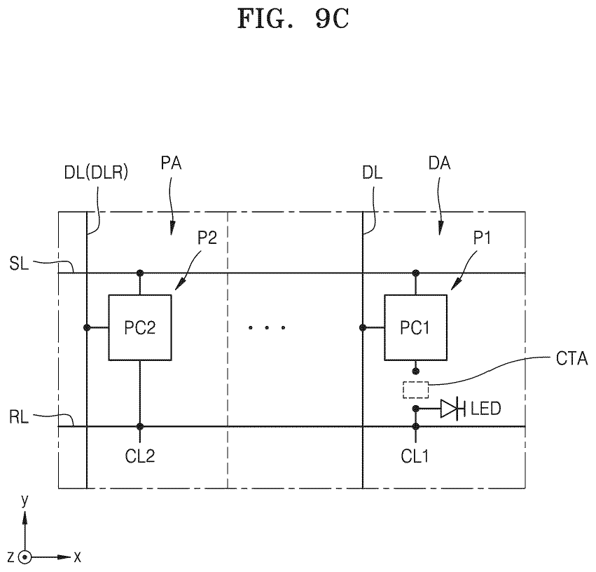

FIGS. 9A to 9C are schematic plan views showing an operation in a process of manufacturing a display apparatus according to an embodiment.

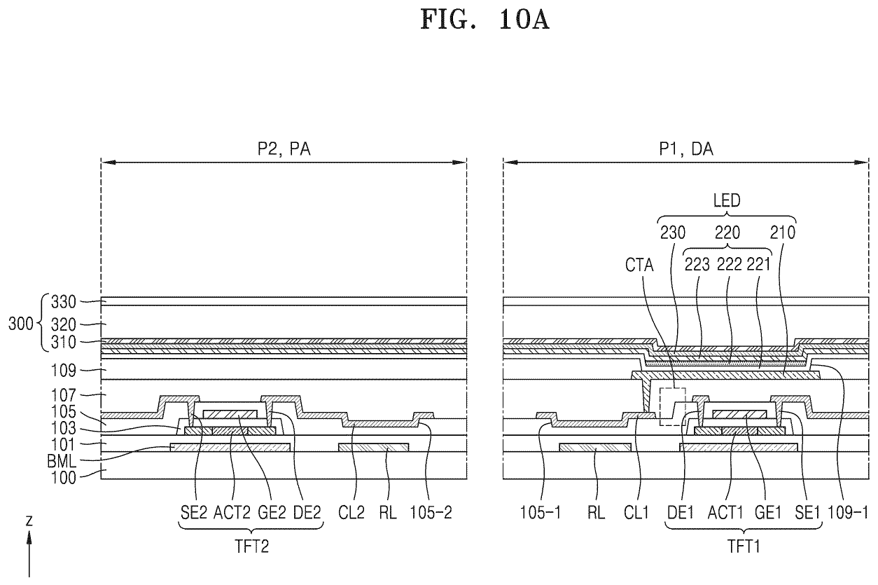

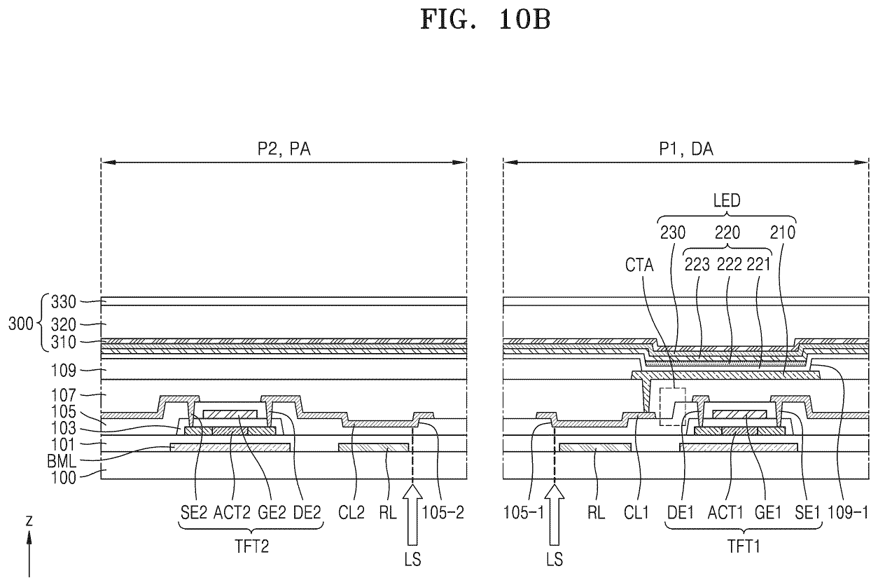

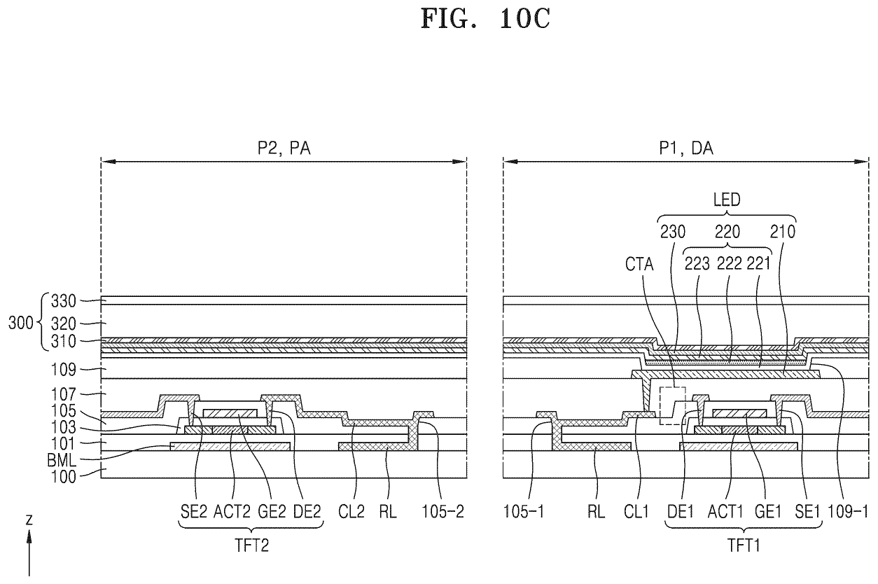

FIGS. 10A to 10C are cross-sectional views showing an operation of connecting the light-emitting diode LED to the second sub-pixel circuit PC2 in a specific circumstance described with reference to FIGS. 3 and 4.

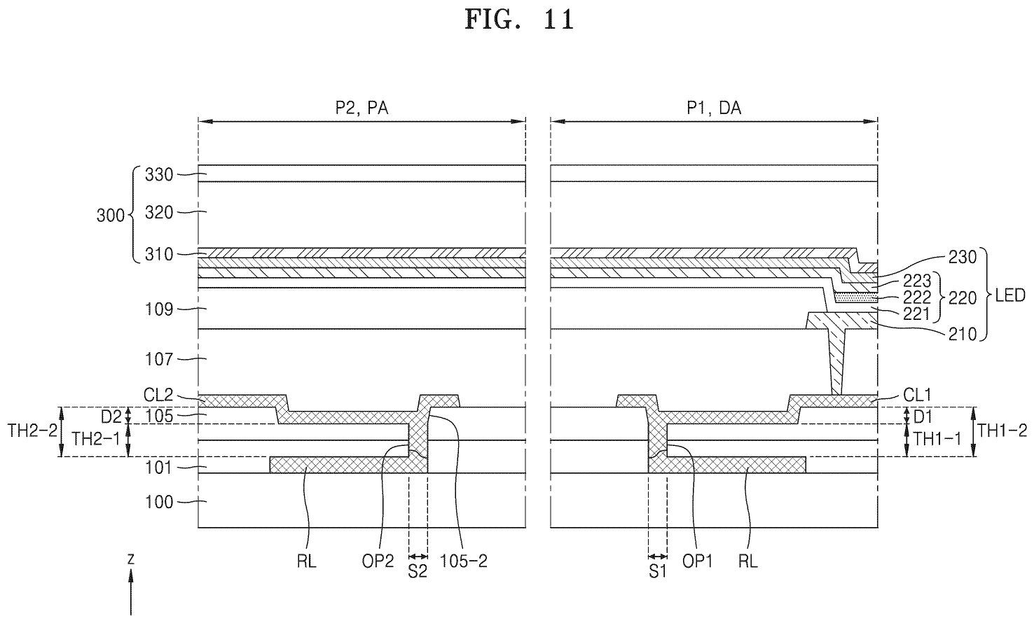

FIG. 11 is an enlarged cross-sectional view of a portion of FIG. 10C.

First, referring to FIG. 9A, in the case where a defect occurs in the first sub-pixel circuit PC1, and the light-emitting diode LED does not normally operate, a portion of the first connection line CL1 connecting the light-emitting diode LED to the first sub-pixel circuit PC1 may be cut. As an example, the first connection line CL1 may be cut in a cutting area CTA located between the light-emitting diode LED and the first sub-pixel circuit PC1. The cutting process may be performed with a laser beam. FIG. 9B shows a state in which a portion of the first connection line CL1 is cut. In the state shown in FIG. 9B, there may be no sub-pixel circuit connected to the light-emitting diode LED.

Then, referring to FIG. 9C, the first connection line CL1 may be connected to the repair line RL, and the second connection line CL2 may be connected to the repair line RL. The connecting process may be performed with a laser beam. The connecting of the first connection line CL1 and the repair line RL and the connecting of the second connection line CL2 and the repair line RL may be simultaneously performed, sequentially performed, or performed in any order. Accordingly, the light-emitting diode LED may be connected to the second sub-pixel circuit PC2 through the first connection line CL1, the repair line RL, and the second connection line CL2, and may be turned on normally. Through this process, a lighting defect of a sub-pixel that occurs due to a defect in a sub-pixel circuit during the process of manufacturing the display apparatus may be reduced.

The connecting of the first connection line CL1 to the repair line RL and the connecting of the second connection line CL2 to the repair line RL described above with reference to FIGS. 10A to 11 are described below in detail.

First, referring to FIG. 10A, a portion of the line may be cut in the cutting area CTA located between the first connection line CL1 and the first drain electrode DE1. Accordingly, the first connection line CL1 and the first drain electrode DE1 may be disposed apart from each other. Although not shown in FIG. 10A, during a process of cutting the line using a laser beam, an opening under the cutting area may be formed in the interlayer insulating layer 105 and the buffer layer 101.

Then, referring to FIG. 10B, a laser beam LS may irradiate the pixel in a +z direction from the rear surface of the substrate 100. For example, the laser beam LS may be directed toward the lower surface of the first connection line CL1 from the rear surface of the substrate 100. The laser beam LS may be directed toward an end of the first groove 105-1 and next to the repair line RL, such that the repair line RL is not in the line of the beam. In some embodiments, the laser beam LS may be adjacent to the repair line RL and irradiate the lateral surface of the repair line RL.

Similarly, another laser beam LS may be directed toward the lower surface of the second connection line CL2 from the rear surface of the substrate 100. The laser beam LS may be directed toward an end of the second groove 105-2 and next to the repair line RL. In some embodiments, the laser beam LS may be adjacent to the repair line RL and irradiate the lateral surface of the repair line RL.

Each laser beam may pass through the buffer layer 101 and the interlayer insulating layer 105 and form an opening in the buffer layer 101 and the interlayer insulating layer 105. Simultaneously, the laser beam LS may irradiate the lateral surface of the repair line RL and heat and melt a portion of the repair line RL. A portion of the lower surface of the first connection line CL1 and a portion of the lower surface of the second connection line CL2 may be molten by heating the lower surfaces of the first connection line CL1 and the second connection line CL2.

Subsequently, referring to FIGS. 10C and 11 together, the laser beam may be turned off or removed. A first opening OP1 may be formed in the buffer layer 101 and the interlayer insulating layer 105. A portion of the first connection line CL1 and a portion of the repair line RL molten by the laser beam may fill the first opening OP1, connecting the first connection line CL1 to the repair line RL. With the laser beam turned of, the first connection line CL1 and the repair line RL may solidify. Accordingly, the first connection line CL1 and the repair line RL may be electrically connected to each other. During this process, the boundary surface between the first connection line CL1 and the repair line RL may be located in the first opening OP1.

Similarly, a second opening OP2 may be formed in the buffer layer 101 and the interlayer insulating layer 105. A portion of the second connection line CL2 and a portion of the repair line RL molten by the laser beam may fill the second opening OP2, connecting the second connection line CL2 to the repair line RL. With the laser beam turned off, the second connection line CL2 and the repair line RL may solidify. Accordingly, the second connection line CL2 and the repair line RL may be electrically connected to each other. During this process, the boundary surface between the second connection line CL2 and the repair line RL may be located in the second opening OP2.

As a result, the first connection line CL1, the repair line RL, and the second connection line CL2 may be electrically connected to each other.

During this process, when the thickness of the insulating layer between the first connection line CL1 and the repair line RL, or between the second connection line CL2 and the repair line RL is too thick, there may be difficulties in connecting the two lines with laser. In contrast, because the display apparatus according to the disclosure includes the first groove 105-1 and the second groove 105-2 formed in the interlayer insulating layer 105, these difficulties may be reducedd. In other words, in the display apparatus according to the disclosure, because the first-1 thickness TH1-1 and the second-1 thickness TH2-1 are formed to be less than the first-2 thickness TH1-2 and the second-2 thickness TH2-2, a connection success rate of the first connection line CL1 and the repair line RL and/or a connection success rate of the second connection line CL2 and the repair line RL through the laser beam irradiation may increase.

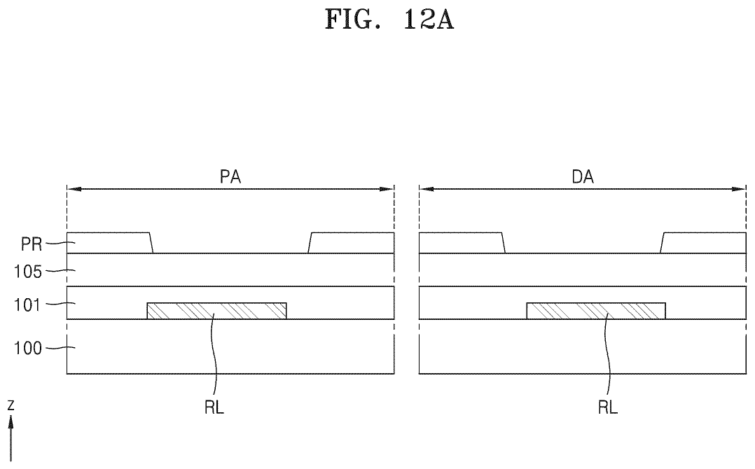

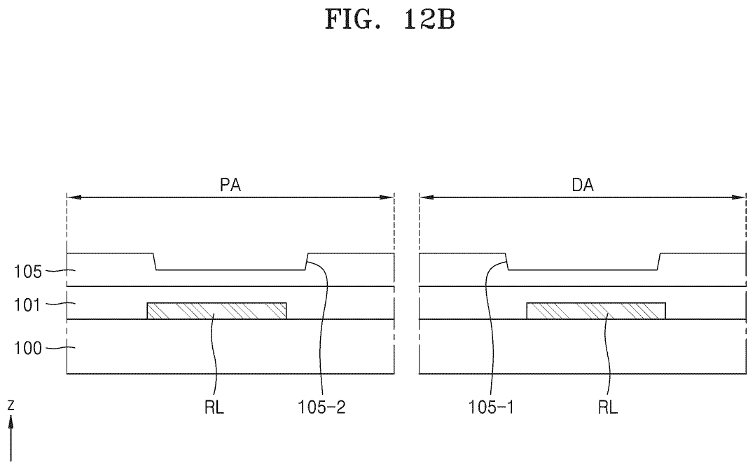

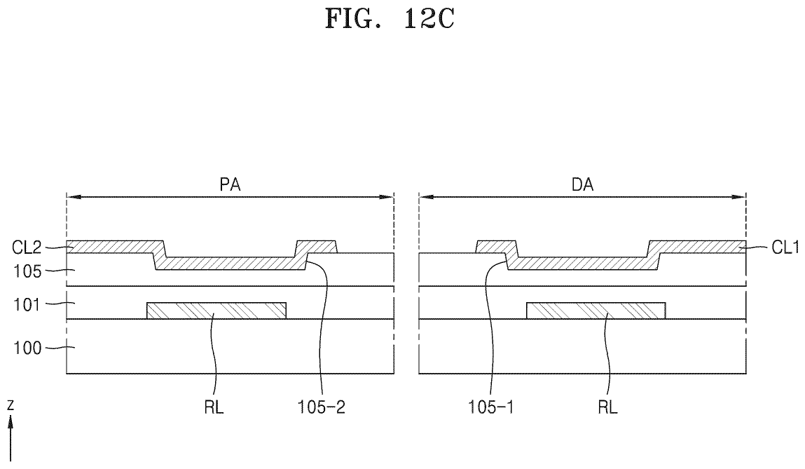

FIGS. 12A to 12C are cross-sectional views showing an operation in a process of manufacturing a display apparatus according to an embodiment.

FIGS. 12A to 12C show processes of forming the groove of the interlayer insulating layer 105 of the display apparatus according to the disclosure. Although description is made based on the interlayer insulating layer 105 in FIGS. 12A to 12C, a groove may be formed also in the buffer layer 101 in a similar method.

Referring to FIG. 12A, a photoresist PR may be disposed on the interlayer insulating layer 105. The photoresist PR may include an opening overlapping the repair line RL.

Referring to FIG. 12B, a portion of the interlayer insulating layer 105 may be etched using the photoresist PR as a mask. Accordingly, the first groove 105-1 and the second groove 105-2 may be formed. The depth of the first groove 105-1 and the depth of the second groove 105-2 may be adjusted by the thickness of the photoresist PR. The disclosure is not limited thereto and the first groove 105-1 and the second groove 105-2 may be formed by providing a mask other than the photoresist PR.

Then, referring to FIG. 12C, the first connection line CL1 and the second connection line CL2 may be disposed on the interlayer insulating layer 105 to respectively cover the first groove 105-1 and the second groove 105-2.

According to an embodiment, the display apparatus with a reduced interval between the repair line and the connection line and with an increased success rate when a repair is tried is provided. However, the above-described effect is just an example, and the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a repair line disposed on the substrate;
an insulating layer covering the repair line;
a first thin-film transistor disposed in the insulating layer;
a first connection line disposed on the insulating layer and at least a portion of the repair line; and
a light-emitting element disposed on the first connection line and connected to the first connection line,
wherein the insulating layer includes a first groove on the repair line.

2. The display apparatus of claim 1, wherein a portion of the first connection line that is on the repair line is disposed in the first groove.

3. The display apparatus of claim 1, wherein the first thin-film transistor includes an active layer including a semiconductor, and the repair line is disposed on a layer located under the active layer.

4. The display apparatus of claim 1, wherein the first connection line is disposed on a same layer as a source electrode or a drain electrode of the first thin-film transistor.

5. The display apparatus of claim 1, wherein a first distance between an upper surface of the repair line and an upper surface of the insulating layer in a region overlapping the first groove, is about 20% to about 80% of a second distance between the upper surface of the repair line and the upper surface of the insulating layer in a region outside of the first groove.

6. The display apparatus of claim 1, wherein a depth of the first groove is about 20% to about 80% of a thickness of the insulating layer.

7. The display apparatus of claim 1, wherein an edge of the repair line and an edge of the first groove are separated from each other in one of a first direction and a second direction by 1 μm or more.

8. The display apparatus of claim 1, further comprising a neighboring line that is disposed under the insulating layer and is adjacent to the repair line, wherein a distance between the repair line and the neighboring line in one of a first direction and a second direction is 2 μm or more.

9. The display apparatus of claim 1, wherein, in a plan view, the repair line extends in a first direction, and the first connection line extends in a second direction crossing the first direction.

10. The display apparatus of claim 9, wherein a portion of the repair line extends in the second direction and overlaps the first connection line.

11. The display apparatus of claim 1, further comprising a first opening extending through the insulating layer between the repair line and a portion of the first connection line that is in the first groove.

12. The display apparatus of claim 11, wherein the repair line and the first connection line fill the first opening in the insulating layer and are in direct contact with each other.

13. The display apparatus of claim 12, wherein the first connection line is disconnected from the first thin-film transistor.

14. The display apparatus of claim 1, further comprising:
a second thin-film transistor that is apart from the light-emitting element and the first thin-film transistor and is disposed in the insulating layer; and
a second connection line connected to the second thin-film transistor,
wherein the insulating layer further includes a second groove, and wherein the repair line, the second groove, and the second connection line overlap.

15. The display apparatus of claim 14, further comprising a second opening extending through the insulating layer between the repair line and a portion of the second connection line that is in the second groove,
wherein the repair line and the second connection line fill the second opening in the insulating layer and are in direct contact with each other.

16. The display apparatus of claim 14, comprising:
a display area in which the light-emitting element, the first thin-film transistor, and the first connection line are arranged, and
a peripheral area in which the second thin-film transistor and the second connection line are arranged,
wherein the peripheral area at least partially surrounds the display area.

17. A display apparatus comprising:
a substrate including a display area in which a light-emitting element is arranged, and a peripheral area surrounding the display area;
a first thin-film transistor disposed on the substrate, in the display area;
a first connection line disposed on the first thin-film transistor, in the display area;
a second thin-film transistor disposed on the substrate, in the peripheral area;
a second connection line disposed on the second thin-film transistor, in the peripheral area;
a repair line extending continuously across the display area and the peripheral area; and
an insulating layer disposed between the repair line and the first and second connection lines,
wherein the repair line is disposed on a layer located under the first thin-film transistor and the second thin-film transistor.

18. The display apparatus of claim 17, wherein the repair line overlaps a portion of the first connection line and a portion of the second connection line.

19. The display apparatus of claim 18, wherein the insulating layer includes a first groove and a second groove, wherein the first groove overlaps the repair line and the first connection line, and the second groove overlaps the repair line and the second connection line.

20. The display apparatus of claim 19, wherein at least one of a depth of the first groove and a depth of the second groove is about 20% to about 80% of a thickness of the insulating layer.

21. The display apparatus of claim 17, wherein the first connection line is disposed on a same layer as a source electrode or a drain electrode of the first thin-film transistor.

22. The display apparatus of claim 17, wherein the repair line extends in a first direction, and at least one of the first connection line and the second connection line extends in a second direction crossing the first direction.

23. The display apparatus of claim 22, wherein a portion of the repair line extends in the second direction and overlaps at least one of the first connection line and the second connection line.

24. The display apparatus of claim 17, further comprising a first opening and a second opening extending through the insulating layer, wherein the first opening extends between the repair line and the first connection line, and a second opening extends between the repair line and the second connection line,
wherein the repair line and the first connection line fill the first opening and are in direct contact with each other, and
wherein the repair line and the second connection line fill the second opening and are in direct contact with each other.

25. The display apparatus of claim 24, wherein the light-emitting element is electrically connected to the second thin-film transistor through the first connection line, the repair line, and the second connection line.

26. An electronic device comprising:
a display apparatus; and
a housing around the display apparatus,
wherein the display apparatus includes:
a substrate;
a repair line disposed on the substrate;
an insulating layer on the repair line;
a first thin-film transistor disposed in the insulating layer;
a first connection line disposed on the insulating layer and overlapping at least a portion of the repair line; and
a light-emitting element disposed on the first connection line and connected to the first connection line,
wherein the insulating layer is thinner in a region above the repair line than in other regions.
